(19) United States
(12) Patent Application Publication
(10) Pub. No.: US 2009/0134451 A1
(43) Pub. Date: May 28, 2009

(54) Semiconductor device and method of fabricating the same

(75) Inventors: Seung-Jae Baik, Seoul (KR); Jin-Tae Noh, Suwon-si (KR); Hong-Suk Kim, Yongin-si (KR); In-Sun Yi, Suwon-si (KR); Si-Young Choi, Seongnam-si (KR); Ki-Hyun Hwang, Seongnam-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/292,543

(22) Filed: Nov. 20, 2008

(30) Foreign Application Priority Data
Nov. 22, 2007 (KR) 10-2007-0119816

(51) Int. Cl. H01L 29/792

(52) U.S. Cl. 257/325; 257/E29.309

(57) ABSTRACT

An example embodiment of a non-volatile memory device and an example embodiment of a method of fabricating the same are provided. The non-volatile memory devices includes a tunnel insulation layer on a semiconductor substrate, a charge storage layer on the tunnel insulation layer, a blocking insulation layer including at least one nano dot on the charge storage layer, and a control gate electrode on the blocking insulation layer.

### FOREIGN PRIORITY STATEMENT

This application claims priority under 35 U.S.C. §119 to Korean Patent Application No. 10-2007-0119816, filed on Nov. 22, 2007, in the Korean Intellectual Property Office, the entire contents of which are incorporated herein by reference.

### BACKGROUND

An example embodiment provides a semiconductor device, and more particularly, a non-volatile memory device and a method of fabricating the same.

A non-volatile memory device is a semiconductor device retaining its stored information even when there is no power supply. A representative example of a non-volatile memory device is a flash memory having the ability to store information, and its ability to store information may be based on whether or not electric charges are accumulated in a floating gate interposed between a control gate and a semiconductor substrate.

If an erasing operation is performed on a non-volatile memory device with a doped silicon/oxide/nitride/oxide/silicon (SONOS) structure and a floating gate, a back tunneling current may flow such that an erasing operation speed can be decreased. During the erasing operation, it is necessary to reduce the back tunneling current and also increase a retention time of the non-volatile memory device in a programmed state.

### SUMMARY

An example embodiment provides a non-volatile memory device for increasing a retention time by reducing an electrical field of a blocking insulation layer.

An example embodiment provides a method of fabricating a non-volatile memory device for increasing a retention time by reducing an electrical field of a blocking insulation layer.

In an example embodiment, a non-volatile memory device comprises a tunnel insulation layer on a semiconductor substrate, a charge storage layer on the tunnel insulation layer, a blocking insulation layer including at least one nano dot on the charge storage layer, and a control gate electrode on the blocking insulation layer.

In an example embodiment, a permittivity of the at least one nano dot is less than a permittivity of the blocking insulation layer.

In an example embodiment, the blocking insulation layer comprises a plurality of upper insulation layers, and at least one of the upper insulation layers includes the at least one nano dot.

In an example embodiment, at least one of the upper insulation layers comprises a different material than at least one of the others.

In an example embodiment, the blocking insulation layer is a higher-k dielectric layer.

In an example embodiment, the higher-k dielectric layer comprises at least one of an aluminum oxide layer, a hafnium aluminum oxide layer, a hafnium silicon oxide nitride layer, a hafnium oxide nitride layer, a zirconium silicon oxide nitride layer, a zirconium oxide nitride layer, a zirconium aluminum oxide layer, and a zirconium oxide layer.

In an example embodiment, the at least one nano dot comprises at least one of silicon, a silicon oxide layer, an aluminum oxide layer, and a silicon oxide nitride layer.

In an example embodiment, the charge storage layer comprises a site where charges are trapped.

In an example embodiment, the control gate electrode comprises a conductive material having a higher work function.

In an example embodiment, the charge storage layer is a floating gate.

In an example embodiment, the at least one nano dot comprises a core and a shell having a different material composition than the core.

In an example embodiment, the core comprises at least one of silicon and germanium, and the shell comprises at least one of silicon germanium and a silicon oxide layer.

In an example embodiment, the at least one nano dot has a spherical form or a semi-spherical form.

In an example embodiment, a non-volatile memory device comprises a tunnel insulation layer, a charge storage layer, a blocking insulation layer, and a control gate electrode, all of which are sequentially stacked on a semiconductor substrate, wherein the blocking insulation layer comprises a higher-k dielectric blocking insulation layer region and a lower-k dielectric blocking insulation layer region disposed in the higher-k dielectric blocking insulation layer region, such that the lower-k dielectric blocking insulation layer region reduces an electric field of the blocking insulation layer.

In an example embodiment, the non-volatile memory device further comprises at least one nano dot within the lower-k dielectric blocking insulation layer region having a permittivity less than the higher-k dielectric blocking region.

In an example embodiment, the at least one nano dots has a spherical form or a semi-spherical form.

In an example embodiment, the at least one nano dot comprises a core and a shell having a different material composition than the core.

In an example embodiment, an electron system comprises a controller, an input/output device, a bus, and a memory device, the memory device including a tunnel insulation layer on a semiconductor substrate, a charge storage layer on the tunnel insulation layer, a blocking insulation layer including at least one nano dot on the charge storage layer, and a control gate electrode on the blocking insulation layer.

In an example embodiment, a permittivity of the at least one nano dot is less than a permittivity of the blocking insulation layer.

In an example embodiment, the electron system further comprises a wired or wireless interface capable of transmitting and receiving data.

In an example embodiment, methods of fabricating a non-volatile memory device include forming a tunnel insulation layer on a semiconductor substrate, forming a charge storage layer on the tunnel insulation layer, forming a blocking insulation layer including a nano dot on the charge storage layer, and forming a control gate electrode on the blocking insulation layer.

In an example embodiment, the nano dot is formed with a permittivity less than that of the blocking insulation layer.

In an example embodiment, forming the blocking insulation layer includes forming the first blocking insulation layer, forming the nano dot in the first blocking insulation layer, and forming a second blocking insulation layer on the semiconductor substrate having the nano dot.

In an example embodiment, forming the blocking insulation layer further includes changing composition of the nano dot by performing a heat treatment process on the semiconductor substrate having the nano dot.

In an example embodiment, the nano dot is silicon and changes into a silicon oxide through a heat treatment process of an oxygen atmosphere.

In an example embodiment, forming the blocking insulation layer includes depositing a material causing a phase separation phenomenon on the semiconductor substrate and simultaneously forming the nano dot and the blocking insulation layer by phase separating the semiconductor substrate through a heat treatment process.

In an example embodiment, the material causing the phase separation phenomenon is a material including aluminum, silicon, and oxygen or a material including hafnium, silicon, and oxygen.

### BRIEF DESCRIPTION OF THE DRAWINGS

The above and other features and advantages of example embodiments will become more apparent by describing them in detail with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a cross-sectional view illustrating a portion of a non-volatile memory device according to an example embodiment.

FIG. 2 is a view illustrating an electric field of a blocking insulation layer including a nano dot according to an example embodiment.

FIG. 3 is a cross-sectional view of a blocking insulation layer according to an example embodiment.

FIG. 4 is a cross-sectional view of a nano dot according to an example embodiment.

FIG. 5 is a graph illustrating characteristics of a leakage current of a non-volatile memory device according to an example embodiment.

FIGS. 6A and 6B are views of a NAND non-volatile memory device according to an example embodiment.

FIGS. 7A and 7B are views of a NOR non-volatile memory device according to an example embodiment.

FIG. 8 is a block diagram illustrating an electronic system including a non-volatile memory device according to an example embodiment.

FIG. 9 is a block diagram of a memory card including a non-volatile memory device according to an example embodiment.

FIG. 10 is a block diagram of a memory connected to a host system according to an example embodiment.

FIG. 11 is a block diagram of the memory card of FIG. 9 is connected to a host system according to an example embodiment.

FIG. 12 is a block diagram of a memory connected to a computer system according to an example embodiment.

### DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

A charge trap flash memory according to an example embodiment includes a charge storage layer, such as an, an insulator, between a control gate and a semiconductor substrate. A tunnel insulation layer may be disposed between the charge storage layer and the semiconductor substrate, and a blocking insulation layer may be disposed between the charge storage layer and the control gate. The charge storage layer includes a trap site for storing charges. Additionally, whether charges are accumulated in the trap site determines the information stored in the charge trap flash memory. The charge trap flash memory has advantages in reducing its limitations for parasite capacitance and a coupling coefficient, compared to a flash memory with a floating gate. During an erasing operation of a charge trap flash memory with a silicon/oxide/nitride/oxide/silicon (SONOS) cell structure, because a back tunneling current through a blocking insulation layer occurs, an erasing operation speed may be decreased. However, using a higher-k dielectric insulation layer as the blocking insulation layer may reduce an electric field applied to the higher-k dielectric insulation layer. For example, a charge trap flash memory with a TaN/Al₂O₃/nitride/oxide/silicon cell structure may be used. If an aluminum oxide layer (Al₂O₃) is used as the higher-k dielectric insulation layer, an electric field applied to the higher-k dielectric insulation layer is reduced such that the back tunneling current flowing through the higher-k dielectric insulation layer can be reduced. Additionally, by using a conductive material (for example, TaN, WN, TiN, CoSix, polysilicon) with a higher work function, such as more than 4.5 eV, as a control gate electrode, the back tunneling current can be further reduced.

A flash memory with a floating gate structure includes a conductive charge storage layer between a control gate and a semiconductor substrate. A tunnel insulation layer may be disposed between the charge storage layer and the semiconductor substrate, and a blocking insulation layer may be disposed between the charge storage layer and the control gate. The floating gate may be formed of a conductive material. Whether charges are accumulated in a floating gate determines the information stored in the flash memory.

The back tunneling current flowing through a blocking insulation layer may depend on an electric field applied to the blocking insulation layer. If a nano dot with the permittivity less than that of the blocking insulation layer is inserted into the blocking insulation layer, an electric field of the blocking insulation layer may be reduced, and the back tunneling current can be reduced.

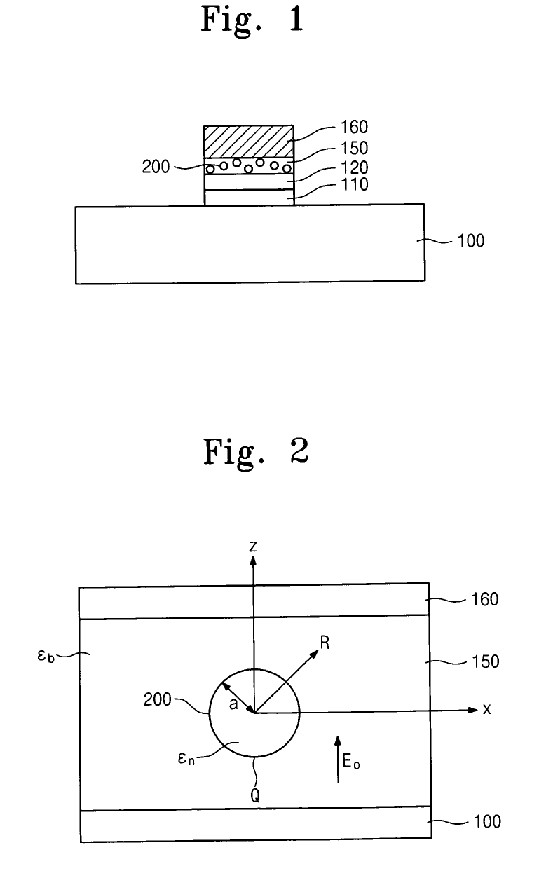

FIG. 1 is a cross-sectional view illustrating a portion of a non-volatile memory device according to an example embodiment.

A non-volatile memory device includes one or more transistor structures shown in FIG. 1. The transistor structure includes a tunnel insulation layer 110 on a semiconductor substrate 100, a charge storage layer 120 on the tunnel insulation layer 110, a blocking insulation layer 150 including at least one nano dot 200 on the charge storage layer 120, and a control gate electrode 160 on the blocking insulation layer 150.

The semiconductor substrate 100 may include one selected from a single crystalline silicon layer, a silicon on insulator (SOI), a silicon layer on a silicon germanium (SiGe) layer, a silicon single crystalline layer on an insulation layer, and a polysilicon layer on an insulation layer.

The tunnel insulation layer 110 may include at least one of a silicon oxide layer, a silicon oxide nitride (SiON) layer, and a high-k dielectric material. The high-k dielectric material may include at least one of an aluminum oxide (Al₂O₃) layer, a hafnium oxide (HfO₂) layer, a hafnium aluminum oxide (HfAlO) layer, a hafnium silicon oxide (HfSiO) layer, a zirconium oxide (ZrO₂) layer, and a tantalum oxide (Ta₂O₅) layer.

The charge storage layer 120 may be formed of a material having traps where charges can be stored. The charge storage layer 120 may include a dielectric layer. The charge storage layer 120 may include at least one of a silicon nitride layer, doped silicon, and doped germanium. The charge storage layer 120 may include at least one selected from nano crystalline silicon, nano crystalline silicon germanium, nano crystalline metal, germanium quantum dot, a metal quantum dot, a silicon quantum dot, and a multilayer structure thereof. The metal includes at least one of a pure metal and a metal compound. The charge storage layer 120 may have a metal trap site through metal doping. Additionally, the charge storage layer 120 may form a deep trap site in an energy band of the charge storage layer through a wet oxidation process after forming the charge storage layer.

The charge storage layer 120 may be a floating gate, and may include a conductive material. The floating gate may include at least one of N-type conductive polysilicon, P-type conductive polysilicon, metal, doped silicon, and doped germanium.

The blocking insulation layer 150 may include a nano dot. The permittivity of the nano dot 200 may be less than that of the blocking insulation layer 150. Accordingly, an electric field of the blocking insulation layer 150 may be reduced. The reduction of an electric field due to the nano dot 200 will be described later. The nano dot 200 may have one of a spherical form or a semi-spherical form, but is not limited thereto. The blocking insulation layer 150 may be a higher-k dielectric layer. The high-k dielectric material may include at least one of an aluminum oxide layer, a hafnium aluminum oxide layer, a hafnium silicon oxide nitride layer, a hafnium oxide nitride layer, a zirconium silicon oxide nitride layer, a zirconium oxide nitride layer, a zirconium aluminum oxide layer, and a zirconium oxide layer. The blocking insulation layer 150 may be formed through atomic layer deposition (ALD), chemical vapor deposition (CVD), and physical vapor deposition (PVD). After forming the blocking insulation layer 150, an anneal process or a plasma treatment process including at least one of O₂, N₂, and NG₃ may be performed.

The control gate electrode 160 may be a conductive material having a given work function. For example, the conductive material of control gate electrode 160 may have a work function of more than 4.5 eV. As a further example, the control gate electrode 160 may include at least one of TaN, polysilicon, W, WN, TiN, and CoSix. The control gate electrode 160 may include another conductive material. To be more specific, the control gate electrode 160 may include a sequentially stacked structure of a barrier metal and a higher work function metal. The higher work function metal may have a work function of more than 4.5 eV. The barrier metal may include at least one of a metal nitride layer, a silicon nitride layer, and a combination thereof, which may reduce or prevent reaction between the higher work function metal and the blocking insulation layer. The control gate electrode 160 may further include at least one of a high work function metal and doped polysilicon between the barrier metal and the blocking insulation layer 150. The control gate electrode 160 may include at least one of sequentially stacked doped silicon and metal, a pure metal, and a metal container.

FIG. 2 is a view illustrating an electric field of a blocking insulation layer including a nano dot according to an example embodiment. The center of the nano dot 200 is the origin of a spherical coordinate. R is a radial component of the spherical coordinate.

Referring to FIG. 2, a blocking insulation layer 150 between a semiconductor substrate 100 and a control gate electrode 160 includes a nano dot 200. An example embodiment of at least one nano dot 200 having a spherical form will be described in the following equations and in FIG. 2. The radius of the spherical nano dot 200 is a. When charges Q are accumulated in the spherical nano dot 200, a uniform electric field E₀ is applied between the semiconductor substrate 100 and the control gate electrode 160. Another layer or layers may be interposed between the blocking insulation layer 150 and the semiconductor substrate 100, but will be omitted for clarity. An external electric field E₂ and an internal electric field E₁ of the nano dot 200 can be expressed as follows:

$$\overline{{E}_{1}} = - \frac{3 {ɛ}_{b} {E}_{0}}{{ɛ}_{n} + {ɛ}_{b}} {\hat{a}}_{z} \\ \overline{{E}_{2}} = {E}_{0} {\hat{a}}_{z} + \frac{{ɛ}_{n} - {ɛ}_{b}}{{ɛ}_{n} + 2 {ɛ}_{b}} \frac{{a}^{3} {E}_{0}}{{R}^{3}} ( 2 cos θ {\hat{a}}_{R} + sin θ {\hat{a}}_{θ} ) + \frac{Q}{4 {πɛ}_{b} {R}^{2}} {\hat{a}}_{R} \qquad [ Equation 1 ]$$

where εₙ is the permittivity of the nano dot 200 and ε_{b} is the permittivity of the blocking insulation layer 150.

If the permittivity of the nano dot 200 is less than that of the blocking insulation layer 150, the external electric field E₂ of the nano dot 200 may be less than the external uniform electric field E₀. Accordingly, a back tunneling current flowing through the blocking insulation layer 150 may be reduced. It will be appreciated that this may be similarly applied to an example embodiment of a nano dot having a semi-spherical form. The charges Q of the nano dot 200 may depend on a difference between band gaps or work functions of the blocking insulation layer 150 and the nano dot 200. Therefore, by adjusting the band gaps of the blocking insulation layer 150 and the nano dot 200, the charges Q of the nano dot 200 can be controlled. The nano dot 200 may be formed of a plurality of layers.

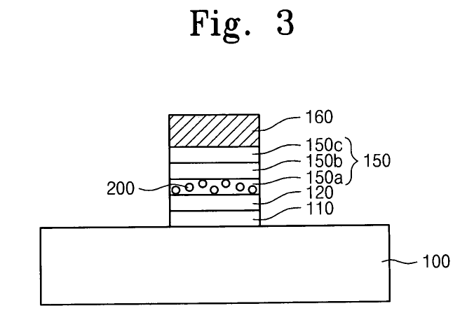

FIG. 3 is a cross-sectional view of a blocking insulation layer according to an example embodiment.

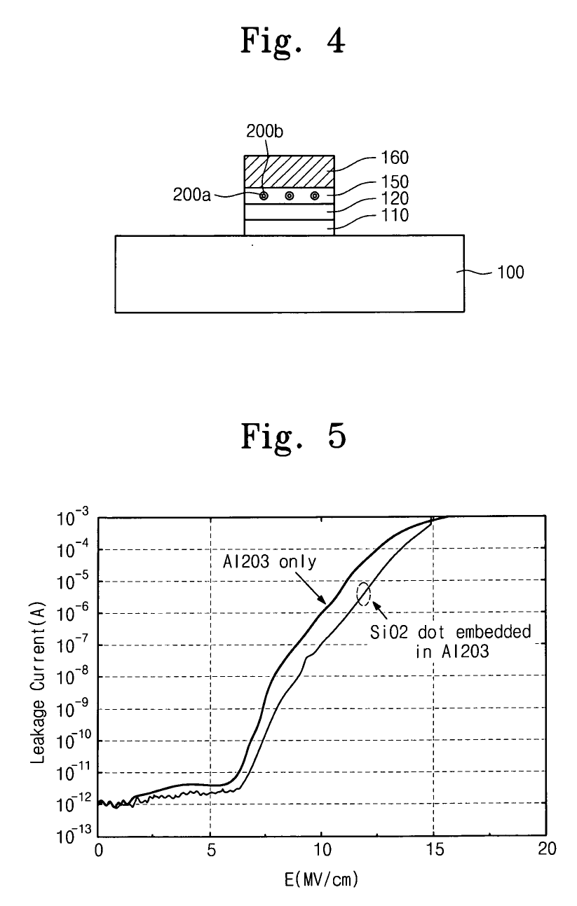

Referring to FIG. 3, a charge storage layer 120 is disposed below a blocking insulation layer 150, and a control gate electrode 160 is disposed on the blocking insulation layer 150. The blocking insulation layer 150 includes a plurality of insulation layers. The plurality of insulation layers includes a first insulation layer 150a, a second insulation layer 150b, and a third insulation layer 150c. At least one of the first to third insulation layers 150a to 150c may include at least one nano dot 200. FIG. 4 is a cross-sectional view of an example embodiment where the nano dot 200 is disposed in the first insulation layer 150a. At least one of the first to third insulation layers 150a to 150c may be formed of a different material than at least one of the others. According to a further example embodiment, the nano dot 200 may be disposed extending over the insulation layers 150a, 150b, and 150c.

FIG. 4 is a cross-sectional view of a nano dot according to an example embodiment.

Referring to FIG. 4, a semiconductor device includes a tunnel insulation layer 110 on a semiconductor substrate 100, a charge storage layer 120 on the tunnel insulation layer 110, a blocking insulation layer 150 including at least one nano dot 200 on the charge storage layer 120, and a control gate electrode 160 on the blocking insulation layer 150. The blocking insulation layer 150 includes at least one nano dot 200, which may have a spherical form. The nano dot 200 includes a core 200b and a shell 200a, and material compositions of the core 200b and the shell 200a may be different. The permittivity and work function of the core 200b may be different from that of the shell 200a. The core 200b may include at least one of silicon and germanium, and the shell 200a may include at least one of silicon germanium and silicon oxide layer. For example, the core 200b and the shell 200a may include respective combinations such as Si₃N₄/SiO₂, Si₃N₄/SiON, SiO₂/Si₃N₄, SiO₂/SiON, Al₂O₃/SiO₂, and SiO₂/Al₂O₃.

FIG. 5 is a graph illustrating characteristics of a leakage current of a non-volatile memory device according to an example embodiment. The x-axis is an electric field (MV/cm) applied to the blocking insulation layer 150, and the y-axis is a leakage current.

Referring to FIG. 5, compared to when the blocking insulation layer 150 is an aluminum oxide layer (Al₂O₃), a leakage current is smaller when the blocking insulation layer 150 includes the nano dot 200 formed of a silicon oxide. A leakage current may vary with the concentration and position of the nano dot 200 in the blocking insulation layer 200, and a semiconductor including the blocking insulation layer 150 with the nano dot 200 may exhibit enhanced reliability.

A method of fabricating a non-volatile memory device will be described according to an example embodiment.

Referring to FIG. 1, a method of fabricating the non-volatile memory device includes forming a tunnel insulation layer 110 on a semiconductor substrate 100, forming the charge storage layer 120 on the tunnel insulation layer 110, forming the blocking insulation layer 150 including the nano dot 200 on the charge storage layer 120, and forming the control gate electrode 160 on the blocking insulation layer 150. The nano dot 200 may be formed with the less permittivity than the blocking insulation layer 150.

Forming the blocking insulation layer 150 includes forming at least one insulation layer (not shown), forming a nano dot 200 in at least oneinsulation layer, and forming at least one other insulation layer (not shown) on the semiconductor substrate 100. Forming of the blocking insulation layer 150 may further include changing the composition of the nano dot 200 by performing a heat treatment process on the semiconductor substrate having the nano dot 200. For example, if the nano dot 200 is silicon, the nano dot 200 may be changed into silicon oxide through a heat treatment in an oxygen atmosphere. The process of forming of the blocking insulation layer may be performed repeatedly.

Forming the blocking insulation layer 150 includes depositing a material causing a phase separation phenomenon on the semiconductor substrate 100, and simultaneously forming the nano dot 200 and the blocking insulation layer 150 by phase separating the semiconductor substrate 100 through a heat treatment process. The material causing a phase separation phenomenon may be a material of silicon, oxygen, and aluminum or a material of silicon, oxygen, and hafnium. In one example embodiment, a material of silicon, oxygen, and aluminum is deposited on the semiconductor substrate 100. Through a heat treatment process on the semiconductor substrate 100, the silicon and oxygen form silicon oxide grains, and aluminum and oxygen form an aluminum oxide layer. In this example, the nano dot 200 may be the silicon oxide grain and the blocking insulation layer may be the aluminum oxide layer. In another example embodiment, a material including silicon, oxygen, and hafnium is deposited on the semiconductor substrate 100, and then through a heat treatment process on the semiconductor substrate 100, the nano dot 200 and the blocking insulation layer 150 may be simultaneously formed. In this example, the nano dot 200 may be in a silicon oxide layer, and the blocking insulation layer 150 may be a hafnium oxide layer. The blocking insulation layer 150 may be formed on the semiconductor substrate having the nano dot 200.

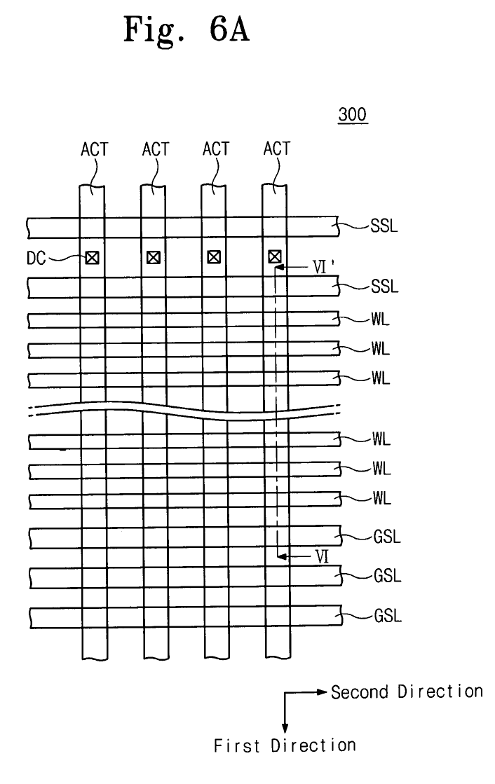

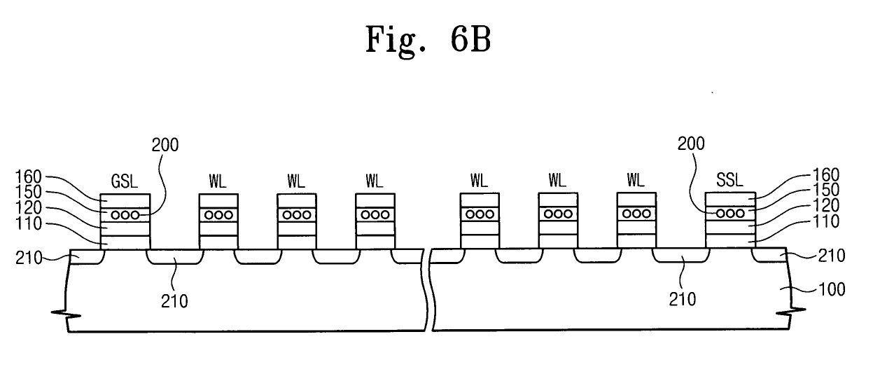

FIGS. 6A and 6B are views of a NAND non-volatile memory device according to an example embodiment. FIG. 6B is a cross-sectional view taken along a line VI-VI′ of FIG. 6A

Referring to FIGS. 6A and 6B, the NAND non-volatile memory device includes a semiconductor substrate 100 having a cell region. A device isolation layer is disposed on the semiconductor substrate 100. The device isolation layer defines active regions ACT. The active regions ACT are laterally arranged in a first direction. A string selection line SSL and a ground selection line GSL cross over the active regions ACT laterally. Word lines WL cross over the active regions ACT laterally between the string selection line SSL and the ground selection line GSL. The string selection line SSL, the ground selection line GSL, and the word lines WL extend along a second direction intersecting the first direction. The string selection line SSL, the word lines WL, and the ground selection line GSL may be included in a cell string group. The cell string group may be repeatedly disposed symmetrically along the first direction.

Impurity regions 210 corresponding to a source and a drain may be disposed on the both sides of the active region ACT of the string selection line SSL, the word line WL, and the ground selection line GSL. The word line WL and the impurity regions 210 on both sides of the word line WL constitute a cell transistor, and the ground selection line GSL and the impurity regions 210 on both sides of the ground selection line constitute a ground selection transistor. The string selection line SSL and the impurity regions 210 on both sides of the string selection line SSL constitute a string selection transistor.

The word lines WL include a tunnel insulation layer 110, a charge storage layer 120, a blocking insulation layer 150, and a control gate electrode 160, which are sequentially stacked on the semiconductor substrate 100. A hard mask pattern (not shown) is disposed on the control gate electrode 160. The ground selection line GSL and the string selection line SSL may have the same structure as the word line WL. However, the line widths of the string selection line SSL and the ground selection line GSL may be different from those of the word lines WL. For example, the line widths of the string selection line SSL and the ground selection line GSL may be greater than those of the word lines WL. Layers corresponding to the tunnel insulation layer 110, the charge storage layer 120, and the blocking insulating layer 150 in the ground and string selection lines GSL and SSL may be used as gate insulation layers of the ground and string selection transistors.

The tunnel insulation layer 110, the charge storage layer 120, and the blocking insulation layer 150 may extend on adjacent semiconductor substrate. The word line WL may share the tunnel insulation layer 110, the charge storage layer 120, and the blocking insulation layer 150. Additionally, the ground and string selection lines GSL and SSL may share the extended tunnel insulation layer 110, charge storage layer 120, and blocking insulation layer 150. A cell spacer (not shown) may be disposed on the sidewalls of the control gate electrode 160. The cell spacer (not shown) may be disposed on the extended blocking insulation layer 150. The blocking insulation layer 150 includes the nano dot 200, and the permittivity of the nano dot 200 may be less than that of the blocking insulation layer 150. In an example embodiment of a charge trap type non-volatile memory device, the tunnel insulation layer 110 and the charge storage layer 120 may be shared by the word lines WL. It will be appreciated that the non-volatile memory device is not limited to a charge trap type example embodiment and may be applied to a floating gate type.

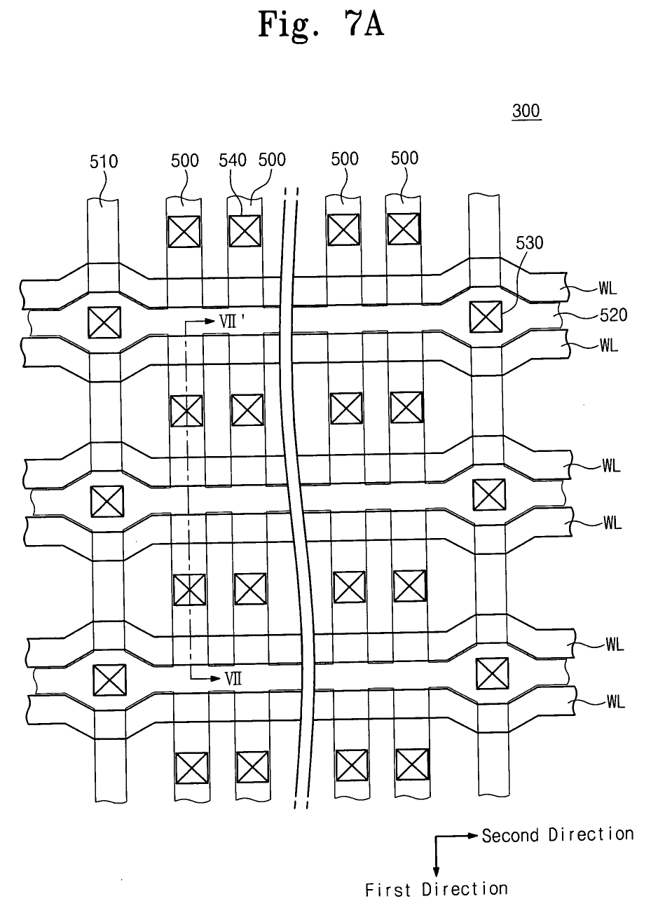

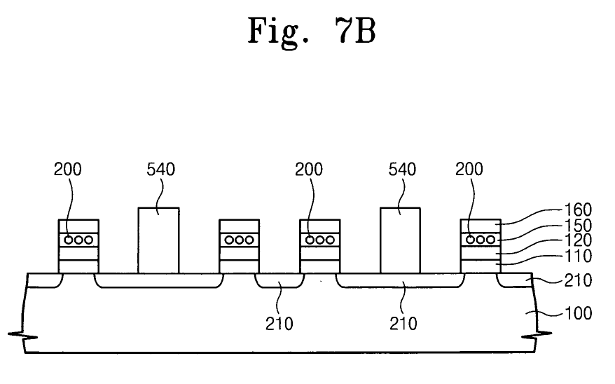

FIGS. 7A and 7B are views of a NOR non-volatile memory device according to an example embodiment. FIG. 7B is a cross sectional view taken along a line VII-VII′ of FIG. 7A.

Referring to FIGS. 7A and 7B, a NOR non-volatile memory device includes a semiconductor substrate 100 having a cell region. A device isolation layer is disposed on the semiconductor substrate 100. The device isolation layer defines active regions 500, 510, and 520. The first active region 500 may be laterally arranged in a first direction. Source strapping active regions 510 are arranged between the first active regions 500 in the first direction. The second active regions 520 intersecting the first active regions 500 are laterally disposed in the second direction. The second active regions 520 may serve as a source line.

A pair of the word lines WL crosses over on the first active regions 500 and the source strapping active regions 510, and are disposed in the second direction. The active regions on the sides of the pair of the word lines WL become drains and sources, respectively. The drain of the transistor is electrically connected to a bit line through a bit line contact plug 540.

The source of the transistor is electrically connected to an adjacent source in the second direction through the second active region 520, and the second active region 520 serves as a source line. A source contact 530 is formed on an intersection region of the second active region 520 and the source strapping active region 510.

The word line WL includes a tunnel insulation layer 110, a charge storage layer 120, a blocking insulation layer 150, and a control gate electrode 160, which are sequentially stacked on the semiconductor substrate 100.

The tunnel insulation layer 110, the charge storage layer 120, and the blocking insulation layer 150 may extend in the second direction. The word line WL may share the tunnel insulation layer 110, the charge storage layer 120, and the blocking insulation layer 150. A spacer (not shown) may be disposed on the extended blocking insulation layer 150. The blocking insulation layer 150 includes a nano dot 200, and the permittivity of the nano dot 200 may be less than that of the blocking insulation layer 150.

An example embodiment of a non-volatile memory device may be included in an electron system.

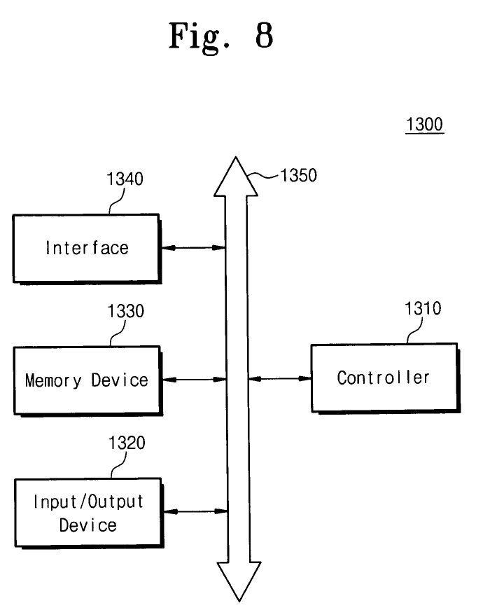

FIG. 8 is a block diagram illustrating a system including a non-volatile memory device according to an example embodiment.

Referring to FIG. 8, an electronic system 1300 includes a controller 1310, an input/output device 1320, and a memory device 1330. The controller 1310, the input/output device 1320, and the memory device 1330 may be connected to each other through a bus 1350. The bus 1350 corresponds to a path through which data can transfer. The controller 1310 may include at least one of a microprocessor, a digital signal processor, a microcontroller, and other logic devices capable performing similar functions thereof. The input/output device 1320 may include at least one of a keypad and a display device. The memory device 1330 is a device for storing data. The memory device 1330 may store data or commands that can be executed by the controller 1310. The memory device 1330 may include at least one of the non-volatile memory devices disclosed in the example embodiments. The electronic system 1300 may further include an interface 1340 in order to transmit data to a communication network, or receive data from the communication network. The interface 1340 may have a wire or wireless type. For example, the interface 1340 may include an antenna or a wire/wireless transceiver.

The electronic system 1300 may be realized with a mobile system, a personal computer, an industrial computer, or a system for performing various functions. For example, the mobile system may be a personal digital assistant (PDA), a portable computer, a web tablet, a mobile phone, a wireless phone, a laptop computer, a memory card, a digital music system, or an information transmitting/receiving system. If the electron system 1300 is configured for wireless communication, it may be used in a communication interface protocol for the third communication systems such as Code Division Multiple Access (CDMA), Global System for Mobile Communications (GSM), North American Digital Cellular (NADC), Extended-Time Division Multiple Access (E-TDMA), and CDMA2000.

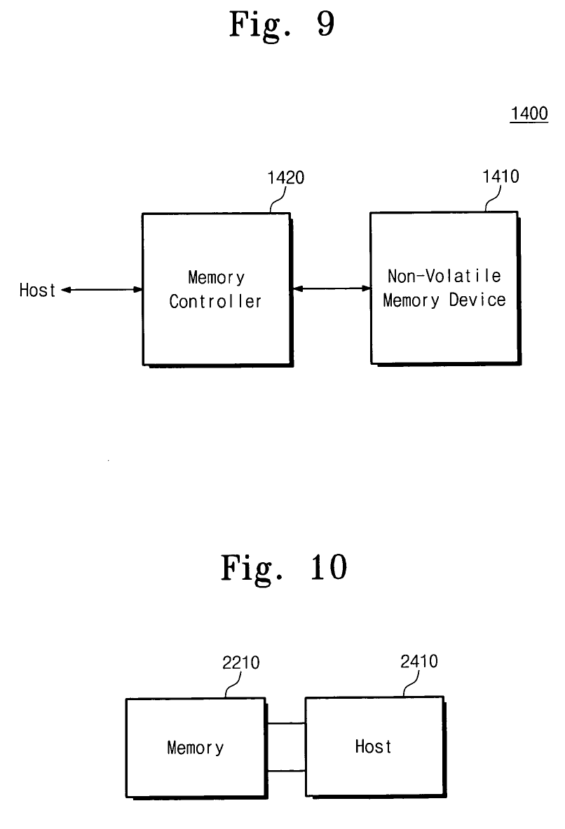

FIG. 9 is a block diagram of a memory card including a non-volatile memory device according to an example embodiment.

Referring to FIG. 9, a memory card 1400 includes a non-volatile memory device 1410 and a memory controller 1420. The non-volatile memory device 1410 can store data and read stored data. The non-volatile memory device 1410 includes at least one of the non-volatile memory devices disclosed in the example embodiments. The memory controller 1420 controls the non-volatile memory device 1410 to read stored data or write data therein in response to a read/write request of a host.

FIG. 10 illustrates an example embodiment where a memory 2210, which may be any of the semiconductor devices described above, may be connected with a host system 2410. The host system 2410 may be a processing system such as a personal computer, digital camera, etc. The host system 2410 may use the memory 2210 as a removable storage medium. As will be appreciated, the host system 2410 supplies the input signals for controlling operation of the memory 2210. For example, the host system 2410 supplies the command CMD and address signals.

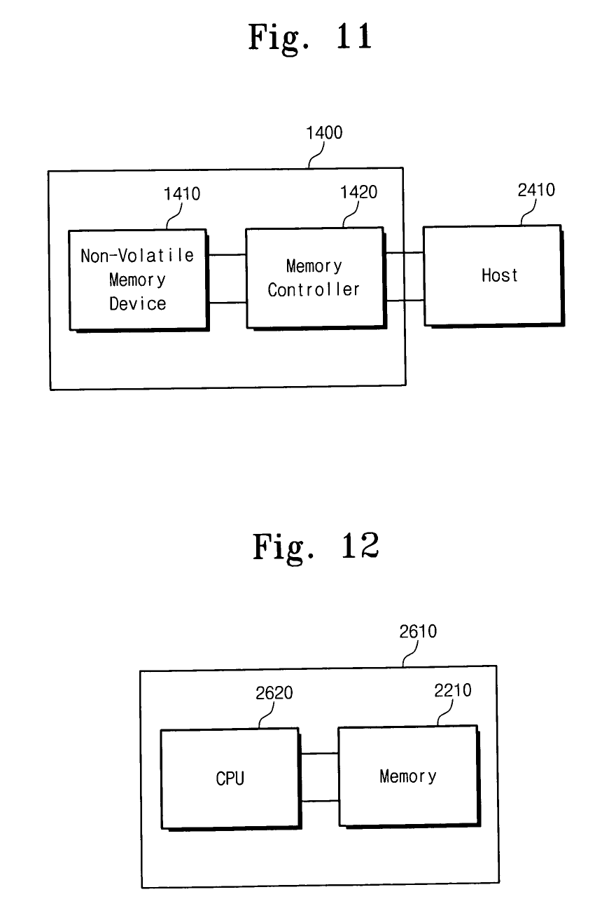

FIG. 11 illustrates an example embodiment in which the host system 2410 is connected to the memory card 1400 of FIG. 9. In this example embodiment, the host system 2410 applies control signals to the memory card 1400 such that the memory controller 1420 controls operation of the non-volatile memory device 1410.

FIG. 12 illustrates an example embodiment where the memory 2210 may be connected to a central processing unit (CPU) 2620 within a computer system 2610. For example, the computer system 2610 may be a personal computer, personal data assistant, etc. The memory 2210 may be directly connected with the CPU 2620, connected via bus, etc. It will be appreciated, that FIG. 12 does not illustrate the full complement of components that may be included within a computer system 2610 for the sake of clarity.

According to an example embodiment, an electric field applied to the blocking insulation layer may be reduced due to a nano dot having less permittivity than a blocking insulation layer. Accordingly, the reliability of a non-volatile memory device can be improved.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A non-volatile memory device comprising:
a tunnel insulation layer on a semiconductor substrate;
a charge storage layer on the tunnel insulation layer;
a blocking insulation layer including at least one nano dot on the charge storage layer; and
a control gate electrode on the blocking insulation layer.

2. The non-volatile memory device of claim 1, wherein a permittivity of the at least one nano dot is less than a permittivity of the blocking insulation layer.

3. The non-volatile memory device of claim 2, wherein the blocking insulation layer comprises a plurality of insulation layers, and at least an upper one of the insulation layers includes the at least one nano dot.

4. The non-volatile memory device of claim 3, wherein at least one of the upper insulation layers comprises a different material than at least one other insulation layer.

5. The non-volatile memory device of claim 2, wherein the blocking insulation layer is a high-k dielectric layer.

6. The non-volatile memory device of claim 5, wherein the high-k dielectric layer comprises at least one of an aluminum oxide layer, a hafnium aluminum oxide layer, a hafnium silicon oxide nitride layer, a hafnium oxide nitride layer, a zirconium silicon oxide nitride layer, a zirconium oxide nitride layer, a zirconium aluminum oxide layer, and a zirconium oxide layer.

7. The non-volatile memory device of claim 2, wherein the at least one nano dot comprises at least one of silicon, a silicon oxide layer, an aluminum oxide layer, and a silicon oxide nitride layer.

8. The non-volatile memory device of claim 2, wherein the at least one nano dot comprises at least one of silicon, silicon and oxygen, aluminum and oxygen, silicon and nitrogen, and nitrogen.

9. The non-volatile memory device of claim 2, wherein the charge storage layer comprises at least one site where charges are trapped.

10. The non-volatile memory device of claim 9, wherein the control gate electrode comprises a conductive material having a work function higher than 4.5 eV.

11. The non-volatile memory device of claim 2, wherein the charge storage layer is a floating gate.

12. The non-volatile memory device of claim 2, wherein the nano dot comprises a core and a shell, and the shell has a different material composition than the core.

13. The non-volatile memory device of claim 12, wherein the core comprises at least one of silicon and germanium, and the shell comprises at least one of silicon germanium and a silicon oxide layer.

14. The non-volatile memory device of claim 2, wherein the nano dot has one of a spherical form and a semi-spherical form.

15. A non-volatile memory device comprising:
a tunnel insulation layer, a charge storage layer, a blocking insulation layer, and a control gate electrode sequentially stacked on a semiconductor substrate,
wherein the blocking insulation layer comprises a higher-k dielectric blocking insulation layer region and a lower-k dielectric blocking insulation layer region disposed in the higher-k dielectric blocking insulation layer region, such that the lower-k dielectric blocking insulation layer region reduces an electric field of the blocking insulation layer.

16. The non-volatile memory device of claim 15, further comprising:
at least one nano dot within the lower-k dielectric blocking insulation layer region having a permittivity less than the higher-k dielectric blocking region.

17. The non-volatile memory device of claim 16, wherein the nano dot has one of a spherical form and a semi-spherical form.

18. The non-volatile memory device of claim 17, wherein the nano dot comprises a core and a shell, and the shell has a different material composition than the core.

19. A non-volatile memory device, comprising:
a nano dot formed in a blocking layer of a transistor structure.

20. The non-volatile memory device of claim 19, wherein a permittivity of the nano dot is less than a permittivity of the blocking layer.
